(19) United States
(12) Patent Application Publication
(10) Pub. No.: US 2013/0141885 A1
(43) Pub. Date: Jun. 6, 2013

(54) HOUSING AND METHOD FOR MAKING HOUSING

(71) Applicants: CHANG-HAI GU, Shenzhen City (CN); JIAN-PING ZHANG, Shenzhen City (CN); HOU-EN XIA, Shenzhen City (CN)

(72) Inventors: CHANG-HAI GU, Shenzhen City (CN); JIAN-PING ZHANG, Shenzhen City (CN); HOU-EN XIA, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/488,944

(22) Filed: Jun. 5, 2012

(30) Foreign Application Priority Data
Dec. 5, 2011 (CN) 201110398411.7

(51) Int. Cl. H05K 7/06; B05D 3/00; B05D 5/12

(52) U.S. Cl. 361/774; 427/58; 427/596

(57) ABSTRACT

A housing of an electronic device is provided, which includes a plastic substrate defining a through hole having an inner wall, and an antenna formed on a surface of the plastic substrate. A conductive element is formed on the inner wall of the substrate through hole to electronically connect to the antenna. The conductive element defines a hole. The conductive element hole is filled with solidified poly-putty base.

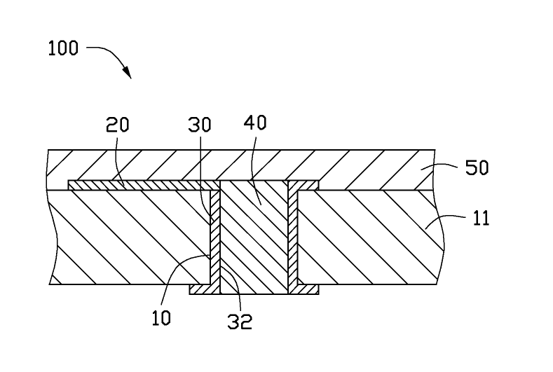

### BACKGROUND

1. Technical Field

The present disclosure relates to a housing and a method for making the housing.

2. Description of Related Art

Electronic devices (e.g. mobile phone) include antennas for transmitting and receiving electromagnetic signals. One kind of antenna is formed on an outside surface of mobile phone housings by plating. To transmit signals from the outside antenna to the inside of the mobile phone, a through hole is defined in the housing, and a copper layer is formed in the through hole to electronically connect the antenna with internal circuitry. However, the through hole is exposed from the housing, and undermines the aesthetics of the housing. Additionally, the through hole may be filled with paint during the subsequent painting process, and may easily cause a non-uniform painted surface.

Therefore, there is room for improvement within the art.

### BRIEF DESCRIPTION OF THE FIGURE

Many aspects of the housing can be better understood with reference to the following drawing. The components in the drawing are not necessarily drawn to scale, the emphasis instead being placed upon clearly illustrating the principles of the housing. Moreover, in the drawing like reference numerals designate corresponding parts throughout the drawing.

The FIGURE is a cross-sectional view of an exemplary embodiment of a housing.

### DETAILED DESCRIPTION

The FIGURE shows a housing 100 according to an exemplary embodiment. The housing 100 includes a plastic substrate 11 defining a through hole 10 and an antenna 20 formed on a surface of the plastic substrate 11. A conductive element 30 is formed on the inner wall of the through hole 10 for electronically connecting to the antenna 20. In this exemplary embodiment, the conductive element 30 is a hollow sleeve, and a hole 32 is defined in the conductive element 30. The antenna 20 and the conductive element 30 are made of a metal material. In an exemplary embodiment, the antenna 20 and the conductive element 30 are made of copper.

Poly-putty base 40 is used for filling the hole 32 and made level with the part of the antenna 20 facing away from substrate 11. The poly-putty base 40 contains unsaturated polyester resin, talc, titanium dioxide, styrene, β-hydroxyethyl methacrylate, benzoic acid, cyclohexanone peroxide, N,N-dimethylaniline, cobalt naphthenate, permanent yellow G and hydroquinone. In this exemplary embodiment, the unsaturated polyester resin has a mass percentage of about 20% to about 30%. The talc has a mass percentage from about 50% to about 60%. The titanium dioxide has a mass percentage of about 2.5%. The styrene has a mass percentage from about 4% to about 8%. The β-hydroxyethyl methacrylate has a mass percentage from about 5% to about 8%. The benzoic acid has a mass percentage of about 2.5%. The cyclohexanone peroxide has a mass percentage of about 2%. The N,N-dimethylaniline has a mass percentage of about 1%. The cobalt naphthenate has a mass percentage of about 0.5%. The permanent yellow G has a mass percentage of about 0.5%. The hydroquinone has a mass percentage of about 0.08%.

A paint layer 50 is disposed on the surface of the plastic substrate 11. The paint layer 50 covers the antenna 20, the conductive element 30 and the poly-putty base 40. Since the sleeve hole 32 is filled with the poly-putty base 40, the paint layer 50 cannot enter and accumulate within the hole 32.

A method for making the housing 100 may include at least the following steps:

The plastic substrate 11 is provided. The through hole 10 is defined in the plastic substrate 11. The plastic substrate 11 is manufactured by injection molding.

The antenna 20 and the conductive element 30 are formed on the plastic substrate 11. In this exemplary embodiment, the antenna 20 and the conductive element 30 is formed by Laser Direct Structuring (LDS) process. First, modified plastic, which can be laser-activated to be conductive, is formed on a predefined region on the plastic substrate 11 and the inner wall of the through hole 10. A laser is focused on the predefined region of the plastic substrate 11 spreading the metal crystals contained in the modified plastics to cover the predefined region. Finally, a conductive metal coating is deposited on the predefined region to form the antenna 20 and the conductive element 30. The antenna 20 is formed on the outside surface of the plastic substrate 11, and the conductive layer 30 is formed on the inner wall of the through hole 10 to connect to the antenna 20 with the internal circuitry. The conductive element 30 defines the hole 32. The conductive layer 30 can transmit the signals from the antenna 20 to the inside of the housing 100.

The poly-putty base 40 is prepared. The poly-putty base 40 contains a main agent and a curing agent. The main agent contains unsaturated polyester resin, talc, titanium dioxide, styrene, β-hydroxyethyl methacrylate, N,N-dimethylaniline, hydroquinone, benzoic acid and cobalt naphthenate. The curing agent contains cyclohexanone peroxide and permanent yellow G. The poly-putty base 40 contains unsaturated polyester resin with a mass percentage from about 20% to about 30%, talc with a mass percentage from about 50% to about 60%, titanium dioxide with a mass percentage of about 2.5%, styrene with a mass percentage from about 4% to about 8%, β-hydroxyethyl methacrylate with a mass percentage from about 5% to about 8%, benzoic acid with a mass percentage of about 2.5%, cyclohexanone peroxide with a mass percentage of about 2%, N,N-dimethylaniline with a mass percentage of about 1%, cobalt naphthenate with a mass percentage of about 0.5%, permanent yellow G with a mass percentage of about 0.5%, and hydroquinone with a mass percentage of about 0.08%.

The poly-putty base 40 is filled in the hole 32 and cures naturally. The main agent and the curing agent in the poly-putty base 40 can crosslink during curing, and form a solidified poly-putty base 40 in the hole 32. The poly-putty base 40 has a high curing speed, strong adhesion, and will not shrink in the hole 32.

The plastic substrate 11 is trimmed and polished to make the surface of the plastic substrate 11 even. The solid poly-putty base 40 is easily polished.

The plastic substrate 11 is coated with a paint layer 50, and the housing 100 is formed. The paint layer 50 covers the antenna 20, the conductive element 30 and the poly-putty base 40, which can protect the antenna 20 and beautify the appearance of the housing 100.

The housing 100 may be a shell of an electronic device, such as a mobile phone.

The method for making the housing 100 can stop the paint from filling in the through hole 10, and give the housing 100 a beautiful appearance.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A housing of an electronic device, comprising:
a plastic substrate defining a through hole having an inner wall; and
an antenna formed on a surface of the plastic substrate;
wherein a conductive element is formed on the inner wall of the substrate through hole to electronically connect to the antenna, the conductive element defines a hole, the conductive element hole is filled with solidified poly-putty base.

2. The housing as claimed in claim 1, wherein the poly-putty base contains unsaturated polyester resin, talc, titanium dioxide, styrene, β-hydroxyethyl methacrylate, benzoic acid, cyclohexanone peroxide, N,N-dimethylaniline, cobalt naphthenate, permanent yellow G and hydroquinone.

3. The housing as claimed in claim 2, wherein the poly-putty base contains unsaturated polyester resin with a mass percentage from about 20% to about 30%, talc with a mass percentage from about 50% to about 60%, titanium dioxide with a mass percentage of about 2.5%, styrene with a mass percentage from about 4% to about 8%, β-hydroxyethyl methacrylate with a mass percentage from about 5% to about 8%, benzoic acid with a mass percentage of about 2.5%, cyclohexanone peroxide with a mass percentage of about 2%, N,N-dimethylaniline with a mass percentage of about 1%, cobalt naphthenate with a mass percentage of about 0.5%, permanent yellow G with a mass percentage of about 0.5%, and hydroquinone with a mass percentage of about 0.08%.

4. The housing as claimed in claim 1, wherein the antenna is made of copper.

5. The housing as claimed in claim 1, wherein the conductive element is made of copper.

6. The housing as claimed in claim 1, wherein the poly-putty base is made level with the part of the antenna facing away from the plastic substrate.

7. The housing as claimed in claim 1, wherein a paint layer is formed on the surface of the plastic substrate, and the paint layer covers the antenna, the conductive element and the poly-putty base.

8. A method for making a housing of an electronic device, comprising:
providing a plastic substrate defining a through hole having an inner wall;
forming an antenna on a surface of the plastic substrate;
forming a conductive element connected to the antenna on the inner wall of the substrate through hole, and the conductive element defining a hole;
filling the conductive element hole with poly-putty base and solidifying the poly-putty base.

9. The method as claimed in claim 8, wherein the poly-putty base contains unsaturated polyester resin with a mass percentage from about 20% to about 30%, talc with a mass percentage from about 50% to about 60%, titanium dioxide with a mass percentage of about 2.5%, styrene with a mass percentage from about 4% to about 8%, β-hydroxyethyl methacrylate with a mass percentage from about 5% to about 8%, benzoic acid with a mass percentage of about 2.5%, cyclohexanone peroxide with a mass percentage of about 2%, N,N-dimethylaniline with a mass percentage of about 1%, cobalt naphthenate with a mass percentage of about 0.5%, permanent yellow G with a mass percentage of about 0.5%, and hydroquinone with a mass percentage of about 0.08%.

10. The method as claimed in claim 8, wherein the antenna is formed by laser direct structuring process.

11. The method as claimed in claim 8, wherein the conductive element is formed by laser direct structuring process.

12. The method as claimed in claim 8, wherein the method further comprises trimming and polishing the housing after the poly-putty base is solidified.

13. The method as claimed in claim 12, wherein the method further comprises forming a paint layer covered the antenna, the conductive element and the poly-putty base after the housing is trimmed and polished.
